(19) United States
(12) Patent Application Publication
(10) Pub. No.: US 2006/0006508 A1
(43) Pub. Date: Jan. 12, 2006

(54) Semiconductor device in which semiconductor chip is mounted on lead frame

(75) Inventor: Takeshi Mitsuhashi, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/172,943

(22) Filed: Jul. 5, 2005

(30) Foreign Application Priority Data
Jul. 5, 2004 (JP) 2004-198365

(51) Int. Cl. H01L 23/495; H01L 21/44

(52) U.S. Cl. 257/676; 257/666; 438/123; 257/673; 257/686; 438/109; 257/783; 438/118

(57) ABSTRACT

A semiconductor device including a lead frame having a plurality of inner leads having end portions and a plurality of outer leads integrated with the inner leads, the inner leads having first surfaces and second surfaces which are opposite to the first surfaces, first plating provided at the end portions of the first surfaces of the inner leads, second plating provided on the second surfaces of the inner leads, a first semiconductor chip mounted on the second surfaces of the inner leads by means of an intervening first adhesion member, a plurality of first bonding pads arranged on the first semiconductor chip, a plurality of first bonding wires connecting the first bonding pads to one of the first plating and second plating, a second semiconductor chip mounted on the first semiconductor chip by means of an intervening second adhesion member, a plurality of second bonding pads arranged on the second semiconductor chip, a plurality of bonding wires connecting the second bonding pads to the other of the first plating and second plating, and a package encapsulating the inner leads, the first and second semiconductor chips, and the first and second bonding wires.

### CROSS REFERENCE TO RELATED APPLICATION

This application is based upon and claims the benefit of priority from the prior Japanese Patent Application No. JP2004-198365 filed on Jul. 5, 2004, the entire contents of which are incorporated herein by reference.

### FIELD OF THE INVENTION

The present invention relates to a semiconductor device in which a semiconductor chip is mounted on a lead frame, and bonding pads on semiconductor chip and the lead frame are electrically connected by bonding wires.

### DESCRIPTION OF THE BACKGROUND

In order to protect a semiconductor chip from the outside environment, packaging of a semiconductor chip is performed. In recent years, various packaging techniques have been developed to meet the demand of miniaturization of electronic equipment.

Examples of packaging of a semiconductor chip are described, for example, in Japanese Patent Disclosure (Kokai) PH06-37238 and Japanese Patent Disclosure (Kokai) PH08-250537.

The semiconductor chip is adhered with die bond resin to a bed portion of a lead frame. Moreover, in order to exchange electrical signals, bonding pads are arranged on a peripheral region of the semiconductor chip and the bonding pads are electrically connected to inner leads of the lead frame by bonding wires.

The package is formed by encapsulating, with an insulating resin, the semiconductor chip mounted on the bed portion, the bonding wires and the inner leads.

Next, an example of packaging of two semiconductor chips is described. Two semiconductor chips are respectively adhered with die bond resins to both surfaces of the bed portion. Moreover, bonding pads are arranged on a peripheral region of each semiconductor chip and the bonding pads are electrically connected to inner leads of the lead frame by bonding wires. The package is formed by encapsulating, with an insulating resin, two semiconductor chips mounted on both surfaces of the bed portion, the bonding wires and the inner leads.

In a case where bonding pads are arranged on a central region of the semiconductor chip, inner leads are far from the bonding pads. Therefore, it is necessary to stretch the bonding wires for connecting the inner leads to the bonding pads. When greatly increased bonding wire length, the bonding wires are readily carried away by the insulating resin and adjacent bonding wires are likely to undergo short-circuiting.

Therefore, when the package is formed using the above-described lead frame, only the semiconductor chip having bonding pads arranged on the peripheral region can be used. In other words, there is a problem that the above-described lead frame has no packaging versatility.

### SUMMARY OF THE INVENTION

According to one aspect of the present invention, there is provided a semiconductor device including a lead frame having a plurality of inner leads having end portions and a plurality of outer leads integrated with the inner leads, the inner leads having first surfaces and second surfaces which are opposite to the first surfaces, first plating provided at the end portions of the first surfaces of the inner leads, second plating provided on the second surfaces of the inner leads, a first semiconductor chip mounted on the second surfaces of the inner leads by means of an intervening first adhesion member, a plurality of first bonding pads arranged on the first semiconductor chip, a plurality of first bonding wires connecting the first bonding pads to one of the first plating and second plating, a second semiconductor chip mounted on the first semiconductor chip by means of an intervening second adhesion member, a plurality of second bonding pads arranged on the second semiconductor chip, a plurality of bonding wires connecting the second bonding pads to the other of the first plating and second plating, and a package encapsulating the inner leads, the first and second semiconductor chips, and the first and second bonding wires.

### BRIEF DESCRIPTION OF THE DRAWINGS

A more complete appreciation of the invention and many of the attendant advantages thereof will be readily obtained as the same become better understood by reference to the following detailed description when considered in connection with the accompany drawings, wherein:

FIG. 1 is a plan view of a semiconductor device according to a first embodiment of the present invention.

FIG. 2 is a sectional view of the semiconductor device shown in FIG. 1.

FIG. 3 is a sectional view of a semiconductor device according to a second embodiment of the present invention.

FIG. 4 is a sectional view of a semiconductor device according to a third embodiment of the present invention.

FIG. 5 is a sectional view of a semiconductor device according to a fourth embodiment of the present invention.

FIG. 6 is a flowchart showing a method of manufacturing the semiconductor devices shown in FIGS. 3 and 4.

### DETAILED DESCRIPTION OF THE INVENTION

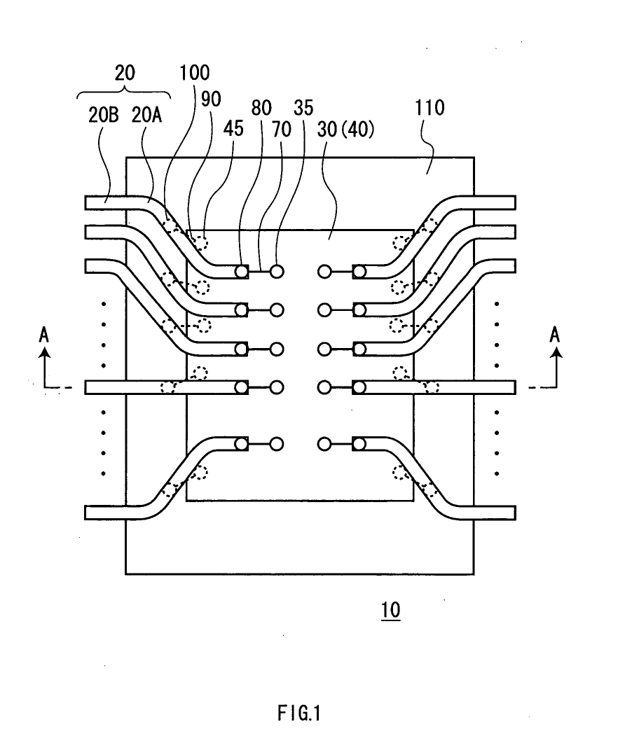

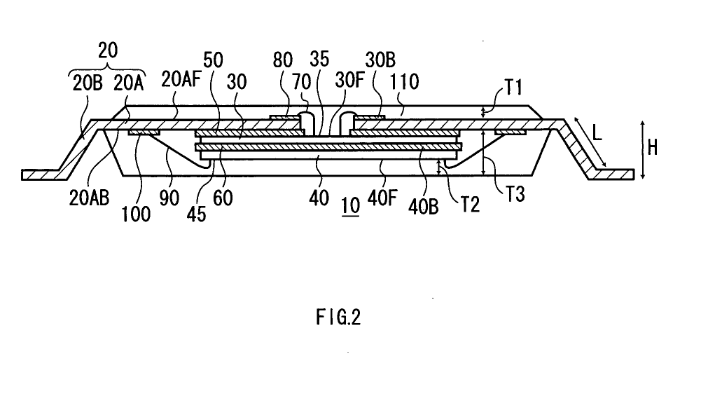

Referring now to the drawings, wherein like reference numerals designate identical or corresponding parts throughout the several views, and more particularly to FIG. 1 thereof, FIG. 1 shows the semiconductor device 10 according to a first embodiment. FIG. 2 shows a sectional view of the semiconductor device 10 along A-A line in FIG. 1. An LOC (Lead On Chip) structure in which a semiconductor chip is mounted on lower surfaces (hereinafter referred to as “back surfaces”) of inner leads is used for the semiconductor device 10 for the purpose of making package size small.

The lead frame 20 has inner leads 20A and outer leads 20B. The inner leads 20A are located inside a package 110. The inner leads 20A are electrically connected to bonding pads 35 and 45. The bonding pads 35 are arranged on a first semiconductor chip 30 and the bonding pads 45 are arranged on a second semiconductor chip 40, respectively. The outer leads 20B are integrated with inner leads 20A.

Insulating die bond tapes 50 are provided at end portions of the back surfaces of the inner leads 20A as adhesion members which prevent deformation of the inner leads 20A and fix the first semiconductor chip 30. The adhesion member is not limited to the insulating die bond tape 50, but another member can be employed to fix the semiconductor chip.

The bonding pads 35 are arranged on a central region of an element formation surface 30F of the first semiconductor chip 30. The element formation surface 30F of the first semiconductor chip 30 is adhered to the inner leads 20A with the insulating die bond tapes 50. The first semiconductor chip 30 is mounted on inner leads 20A via the insulating die bond tapes 50, in a state where the element formation surface 30F of the first semiconductor chip 30 is turned up.

The bonding pads 45 are arranged on a peripheral region of an element formation surface 40F of the second semiconductor chip 40. The element formation surface 40F is not adhered to the first semiconductor chip 30. The insulating die bond tapes 60 are provided on an opposite surface of the first semiconductor chip 30 to the element formation surface 30F. The second semiconductor chip 40 is mounted on the insulating die bond tapes 60, in a state where the element formation surface 40F of the second semiconductor chip 40 is turned down.

The first semiconductor chip 30 and the second semiconductor chip 40 may be a memory and a controller which controls the memory, respectively. The memory may be a NAND-type flash memory.

First plating 80 is provided at end portions of an upper surface 20AF (hereinafter referred to as “front surfaces”) of the inner leads 20A. The bonding pads 35 of the first semiconductor chip 30 are electrically connected to the first plating 80 by first bonding wires 70. The front surfaces 20AF of the inner leads 20A is opposite to a printed circuit board on which the semiconductor device 10 will be mounted.

On the other hand, second plating 100 is provided on back surfaces 20AB of the inner leads 20A. The bonding pads 45 of the second semiconductor chip 40 are electrically connected to the second plating 100 by second bonding wires 90.

A package 110 of the semiconductor device 10 is formed by encapsulating, with an insulating resin, the first semiconductor chip 30, the second semiconductor chip 40, the first bonding wires 70, the second bonding wires 90 and the inner leads 20A. A first distance T1 between the front surfaces 20AF of the inner leads 20A and a front surface of the package 110 is the same as a second distance T2 between the element formation surface 40F (back surface) of the second semiconductor chip 40 and a back surface of the package 110. Furthermore, a third distance T3 between the back surfaces 20AB of the inner leads 20A and the back surface of the package 110 is larger than the first distance T1.

The outer leads 20B are located outside of the package 110. The outer leads 20B are bent toward the printed circuit board on which the semiconductor device 10 will be mounted. In addition, plating is provided at end portions of the outer leads 20B. The plating of the outer leads 20B is connected to the printed circuit board when the semiconductor device 10 is mounted on the printed circuit board.

According to the first embodiment, the same lead frame 20 can be used for mounting the first semiconductor chip 30 of which bonding pads 35 are arranged on the central region of the element formation surface 30F and the second semiconductor chip 40 of which bonding pads 45 are arranged on the peripheral region of the element formation surface 40F.

That is, even if an arrangement of bonding pads differ between the first semiconductor chip 30 and the second semiconductor chip 40, the same lead frame 20 can be used in common. Therefore the packaging versatility can be enhanced without restriction of the arrangement of the bonding pads.

Moreover, high integration is realizable in a thin package by stacking the second semiconductor chip 40 with the first semiconductor chips 30. An electronic equipment system which consists of two or more semiconductor chips can be formed in the same package.

In addition, a curvature of the package can be prevented because the first distance T1 between the front surfaces 20AF of the inner leads 20A and the front surface of the package 110 is same as a second distance T2 between the element formation surface 40F of the second semiconductor chip 40 and the back surface of the package 110.

Furthermore, the first and second semiconductor chips 30 and 40 are mounted on the back surfaces 20AB of inner leads 20A. Therefore, the third distance T3 between the back surfaces 20AB of the inner leads 20A and the back surface of the package 110 is larger than the first distance T1. As compared with the conventional semiconductor device, height H of the outer leads 20B is large and length L of the outer leads 20B can be consequently lengthened. Therefore, the spring effect of the outer-leads 20B can become large, and resistance of the semiconductor device 10 can become strong to stress generated when the printed circuit board is contracted after soldering and mounting the semiconductor device 10 on the printed circuit board.

The present invention is not limited to the first embodiment. For example, only one of the first semiconductor chip 30 and the second semiconductor chip 40 may be mounted.

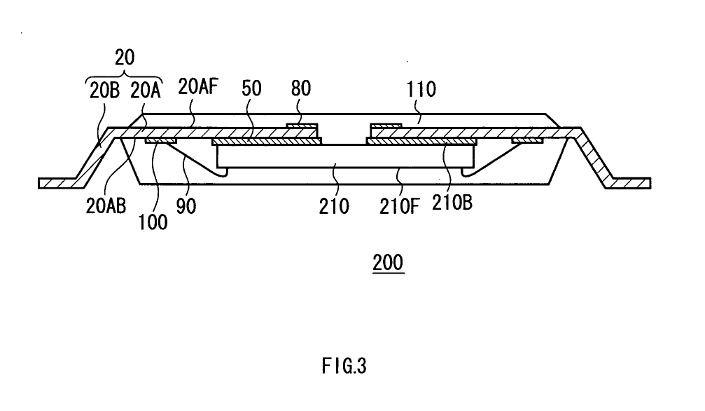

FIG. 3 shows the semiconductor device 200 according to a second embodiment. The semiconductor chip 210 of which bonding pads (not shown) are arranged on a peripheral region of an element formation surface 210F is shown in FIG. 3. The semiconductor chip 210 is adhered to end portions of back surfaces 20AB of the inner leads 20A with the insulating die bond tapes 50, in a state where the element formation surface 210F of the semiconductor chip 210 is turned down.

Second plating 100 is provided on the back surfaces 20AB of the inner leads 20A. The bonding pads of the semiconductor chip 210 are electrically connected to the second plating 100 by second bonding wires 90.

According to the second embodiment, the same lead frame 20 as the first embodiment can be used. Therefore, the versatility on packaging can be raised.

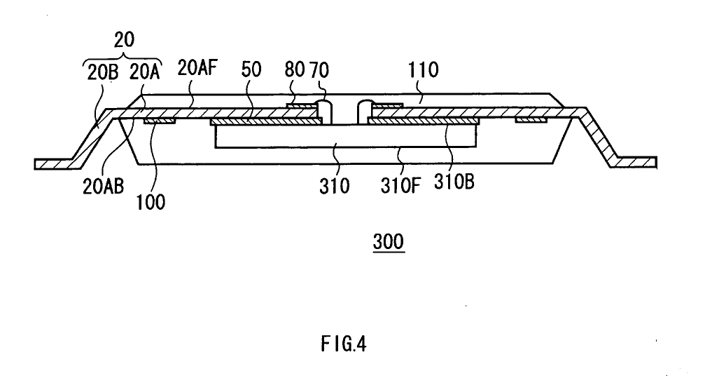

Next, FIG. 4 shows the semiconductor device 300 according to a third embodiment. The semiconductor chip 310 of which bonding pads (not shown) are arranged on a central region of an element formation surface 310F is shown in FIG. 4. The semiconductor chip 310 is adhered to end portions of back surfaces 20AB of the inner leads 20A with the insulating die bond tapes 50, in a state where the element formation surface 310F of the semiconductor chip 310 is turned up.

First plating 80 is provided at end portions of front surfaces 20AF of the inner leads 20A. The bonding pads of the semiconductor chip 310 are electrically connected to the first plating 80 by first bonding wires 70.

According to the third embodiment, the same lead frame 20 as the first embodiments can be used, as well as the second embodiment. Therefore, the versatility on packaging can be raised.

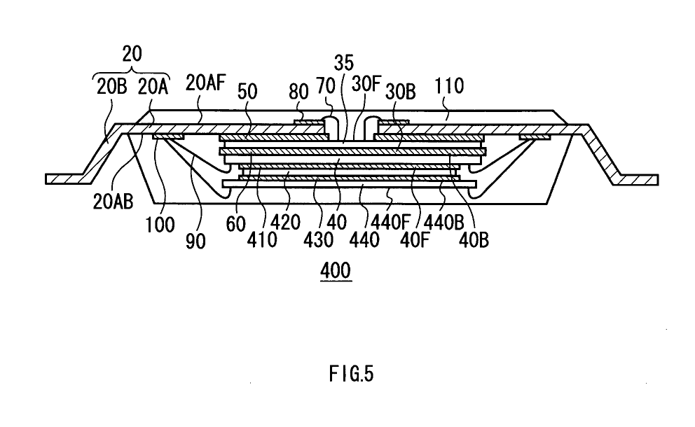

Next, FIG. 5 shows the semiconductor device 400 according to a fourth embodiment. Bonding pads (not shown) are arranged on a peripheral region of an element formation surface 440F of a third semiconductor chip 440. The third semiconductor chip 440 is mounted on the element formation surface 40F of the second semiconductor chip 40 via die bond tapes 410 and a predetermined space member 420.

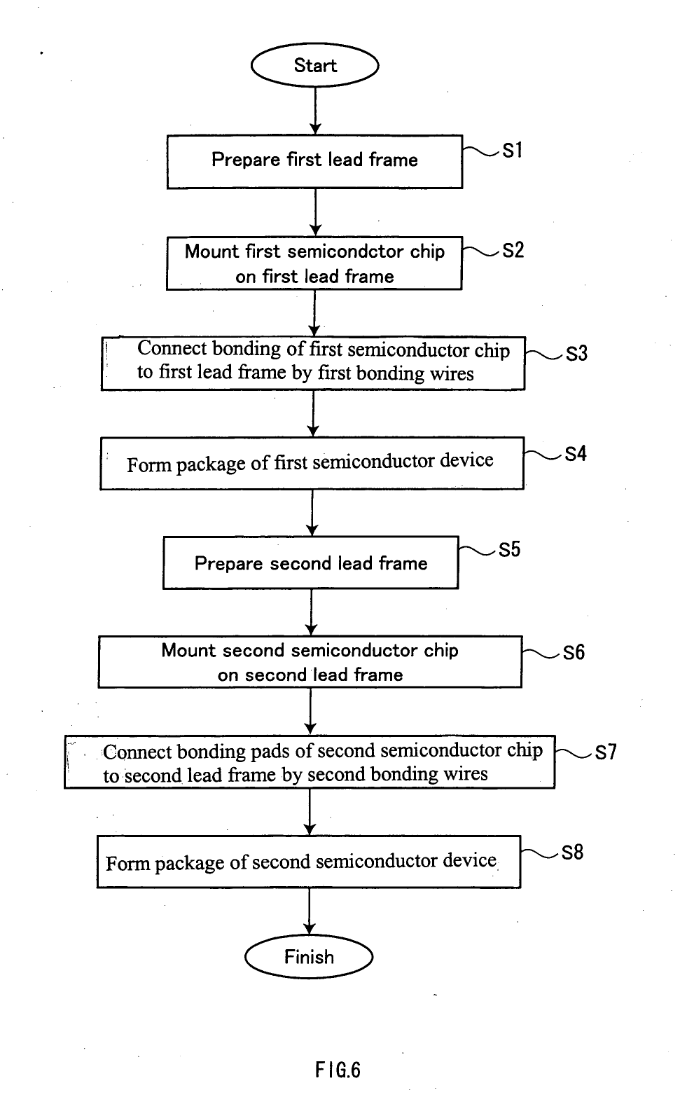

Next, with reference to FIG. 6, a method of manufacturing the semiconductor devices shown in FIG. 3 and 4 will be described. In the flowchart shown in FIG, 6, Steps S1 to S4 are directed to the method of manufacturing the semiconductor devices shown in FIG. 3 (i.e., first semiconductor device) and Steps S5 to S8 are directed to the method of manufacturing the semiconductor devices shown in FIG. 4 (i.e., a second semiconductor device).

First, a first lead frame 20 is prepared (Step S1). The first lead frame 20 has a plurality of first inner leads 20A having end portions, a plurality of first outer leads 20B integrated with the first inner leads 20A, first plating 80 provided at the end portions of front surfaces 20AF of the first inner leads 20A, and second plating 100 provided on back surfaces 20AB of the first inner leads 20A.

Next, a first semiconductor chip 210 is mounted on the back surfaces 20AB of the first lead frame 20A (Step S2). A plurality of first bonding pads are arranged on a peripheral region of an element formation surface 210F of the first semiconductor chip 210. In Step S2, a surface 210B of the first semiconductor chip 210 which is opposite to the element formation surface 210F is attached to the first inner leads 20A.

Next, the first bonding pads are connected to the second plating 100 by a plurality of first bonding wires 90 (Step S3). Then, a package of the first semiconductor device shown in FIG. 3 is formed by encapsulating the first inner leads 20A, the first semiconductor chip 210 and the first bonding wires 90 (Step S4).

Then when manufacturing a second semiconductor device as shown in FIG. 4, a second lead frame 20 is prepared (Step S5). The second lead frame has the same shape as the first lead frame. That is, the second lead frame 20 has a plurality of second inner leads 20A having end portions, a plurality of second outer leads 20B integrated with the second inner leads 20A, third plating 80 provided at the end portions of front surfaces 20AF of the second inner leads 20A, and fourth plating 100 provided on back surfaces 20AB of the second inner leads 20A.

Next, a second semiconductor chip 310 is mounted on the back surfaces 20AB of the second lead frame 20A (Step S6). A plurality of second bonding pads are arranged on a central region of an element formation surface 310F of the second semiconductor chip 310. In Step S6, the element formation surface 310F of the second semiconductor chip 310 is attached to the second inner leads 20A.

Next, the second bonding pads are connected to the third plating 80 by a plurality of second bonding wires 70 (Step S7). Then, a package of the second semiconductor device shown in FIG. 4 is formed by encapsulating the second inner leads 20A, the second semiconductor chip 310 and the second bonding wires 70 (Step S8).

Other embodiments of the present invention will be apparent to those skilled in the art from consideration of the specification and practice of the invention disclosed herein. It is intended that the specification and example embodiment be considered as exemplary only, with a true scope and spirit of the invention being indicated by the following claims.

What is claimed is:

1. A semiconductor device comprising:
a lead frame which has a plurality of inner leads having end portions and a plurality of outer leads integrated with the inner leads, the inner leads having first surfaces and second surfaces which are opposite to the first surfaces;
first plating provided at the end portions of the first surfaces of the inner leads;
second plating provided on the second surfaces of the inner leads;
a first adhesion member provided adjacent the second surfaces of the inner leads of said lead frame;
a first semiconductor chip having a first major surface adjacent and adhering to said first adhesion member and a second major surface opposite thereto, the first semiconductor chip separated from the inner leads of said lead frame by the first adhesion member disposed therebetween;
a plurality of first bonding pads arranged on only one surface of the first semiconductor chip;
a plurality of first bonding wires connecting the first bonding pads to one of the first plating and the second plating;
a second adhesion member provided adjacent the second major surface of the first semiconductor chip and adhering thereto;
a second semiconductor chip having a first major surface adjacent and adhering to said second adhesion member and a second major surface opposite thereto, the second semiconductor chip separated from the first semiconductor chip by the second adhesion member disposed therebetween;
a plurality of second bonding pads arranged on only one surface of the second semiconductor chip;
a plurality of second bonding wires connecting the second bonding pads to the other of the first plating and the second plating; and
a package encapsulating the inner leads, the first and second semiconductor chips and the first and second bonding wires.

2. The semiconductor device according to claim 1, wherein the first bonding pads are arranged on a peripheral region of the second major surface of the semiconductor chip.

3. The semiconductor device according to claim 2, wherein the first bonding wires connect the first bonding pads to the first plating and the second bonding wires connect the second bonding pads to the second plating.

4. The semiconductor device according to claim 3, wherein a first distance between the first surfaces of the inner leads and a first exterior surface of the encapsulating package opposite the first surfaces of the inner leads is T1, and a second distance from the second major surface of the second semiconductor chip to a second exterior surface of the encapsulating package opposite the second surface of the second semiconductor chip is T2, and T1=T2.

5. The semiconductor device according to claim 4, wherein the first major surface of the first semiconductor chip faces the inner leads.

6. The semiconductor device according to claim 3, wherein the first adhesion member comprises an insulating die bond tape provided at end portions of the second surfaces of the inner leads.

7. The semiconductor device according to claim 1, wherein the first bonding pads are arranged on a central region of the first major surface of the first semiconductor chip.

8. The semiconductor device according to claim 7, wherein the first bonding wires connect the first bonding pads to the first plating.

9. The semiconductor device according to claim 8, wherein a first distance between the first surfaces of the inner leads and a first exterior surface of the encapsulating package opposite the first surfaces of the inner leads is T1, and a second distance from the second major surface of the second semiconductor chip to a second exterior surface of the encapsulating package opposite the second surface of the second semiconductor chip is T2, and T1=T2.

10. The semiconductor device according to claim 9, wherein the first major surface of the first semiconductor chip faces the inner leads.

11. The semiconductor device according to claim 8, wherein the first adhesion member comprises an insulating die bond tape provided at the end portions of the second surfaces of the inner leads.

12. A method for manufacturing a first semiconductor device and a second semiconductor device comprising:
preparing a first lead frame which has a plurality of first inner leads having end portions, a plurality of first outer leads integrated with the first inner leads, first plating provided at the end portions of first surfaces of the first inner leads, and second plating provided on second surfaces of the first inner leads which is opposite to the first surfaces;
mounting a first semiconductor chip on the second surfaces of the first lead frame, wherein a plurality of first bonding pads are arranged on the first semiconductor chip;
connecting the first bonding pads to the first plating by a plurality of first bonding wires;
forming a package of the first semiconductor device by encapsulating the first inner leads, the first semiconductor chip and the first bonding wires;
preparing a second lead frame which has a plurality of second inner leads having end portions, a plurality of second outer leads integrated with the second inner leads, third plating provided at the end portions of third surfaces of the second inner leads, and fourth plating provided on fourth surfaces of the second inner leads which is opposite to the third surfaces, wherein the second lead frame has the same shape as the first lead frame;
mounting a second semiconductor chip on the fourth surface of the second lead frame, wherein a plurality of second bonding pads are arranged on the second semiconductor chip;
connecting the second bonding pads to the fourth plating by a plurality of second bonding wires; and
forming a package of the second semiconductor device by encapsulating the second inner leads, the second semiconductor chip and the second bonding wires.

13. The method for manufacturing the first semiconductor device and the second semiconductor device according to claim 12, wherein the first semiconductor chip has first and second major surfaces and the first major surface is mounted adjacent the second surfaces of the first lead frame, the plurality of first bonding pads are arranged on a peripheral region of the second major surface of the first semiconductor chip.

14. The method for manufacturing the first semiconductor device and the second semiconductor device according to claim 13, wherein the second semiconductor chip has first and second major surfaces and the first major surface is mounted adjacent the second surfaces of the second lead frame, and the plurality of second bonding pads are arranged on a central region of a first major surface of the second semiconductor chip.

15. The method for manufacturing the first semiconductor device and the second semiconductor device according to claim 14, wherein the step of mounting the first semiconductor chip includes the step of mounting the first major surface of the first semiconductor chip to the first inner leads.

16. The method for manufacturing the first semiconductor device and the second semiconductor device according to claim 15, wherein the step of mounting the second semiconductor chip includes the step of attaching a first major surface of the second semiconductor chip to the second inner leads.
